(19) United States
(12) Patent Application Publication
(10) Pub. No.: US 2007/0151949 A1
(43) Pub. Date: Jul. 5, 2007

(54) Semiconductor processes and apparatuses thereof

(75) Inventors: Shiu-Ko Jang Jian, Fengshan City (TW); Morning Wu, Linyuan Township (TW); W. T. Huang, Shanhua Township (TW); C. J. Sun, Kaohsiung City (TW)

Correspondence Address: DUANE MORRIS LLP;IP DEPARTMENT (TSMC), 30 SOUTH 17TH STREET, PHILADELPHIA, PA, 19103-4196, US

(73) Assignee: Taiwan Semiconductor manufacturing Co., Ltd.

(21) Appl. No.: 11/326,267

(22) Filed: Jan. 4, 2006

(51) Int. Cl. B44C 1/22; C23F 1/00; H01L 21/306; H01L 21/302

(52) U.S. Cl. 216/83; 438/745; 216/99; 156/345.11

(57) ABSTRACT

Methods of semiconductor processing and apparatuses are disclosed. An organic solvent is applied over a surface of a material layer on a substrate in which the material layer includes a short-chain structure. A fluorine-containing solution is applied over the surface of the material layer to substantially remove the material layer from the substrate. The apparatus comprises the wafer holder coupled to the organic solvent source and the fluorine solution source. The wafer holder accommodates at least one wafer. The organic solvent source supplies an organic solvent with a temperature from about 18° C. to about 40° C., a concentration from about 90 w. % to about 100 w. % and is applied over the substrate about 100 seconds or more. The fluorine solution source containing fluorine solution supplies the fluorine-containing solution with a temperature from about 18° C. to about 70° C. and a concentration from about 1 w. % to about 49 w. %.

### BACKGROUND OF THE INVENTION

1. Field of the Invention

The present invention relates to reclaim processes for control wafer and apparatuses thereof.

2. Description of the Related Art

With the advance of electronic products, semiconductor technology has been widely applied in manufacturing memories, central processing units (CPUs), liquid crystal displays (LCDs), light emitting diodes (LEDs), laser diodes, and the like. For high-integration and high-speed of semiconductor devices, dimensions of semiconductor devices have been shrinking down, and various materials and techniques have been proposed to achieve these requirements and to overcome obstacles confronted during manufacturing.

For example, cross-talk between interlayer metal layers becomes serious due to the size reduction of devices. To suppress the cross-talk, low-k dielectric material has been used to replace traditional silicon diode oxide as the inter-metal dielectric layer so as to solve the problem. Low-k dielectric materials have effectively suppressed signal-propagation delay, cross-talk between metal lines and power consumption due to their low dielectric constants. One of the promising low-k dielectric material is the trimethylsilane (TMS)-based dielectric material. The TMS-based dielectric material is an organosilicate glass with a dielectric constant as low as about 2.1.

Prior to forming a low-k dielectric layer on production wafers, the low-k dielectric layer usually is deposited on a control wafer to assure that physical and electrical characteristics of the low-k dielectric layer satisfy process requirements. Once these characteristics of the low-k dielectric layer tested from the control wafer falls within the specifications, the same recipe used for running the test wafer is set up to process production wafers. After being processed, the control wafer must be transferred to a cleaning station where the low-k dielectric layer is to be removed for recycling. This is also known as a reclaim procedure of control wafers.

FIG. 1 shows a cross-sectional view of a control wafer according to a prior art procedure of control wafer reclaim.

The traditional reclaim procedure of control wafers includes using HF or H₂SO₄ to remove the low-k dielectric layer. The traditional reclaim procedure results in residue 105 of the low-k dielectric material on the wafer 100 as shown in FIG. 1. Residue 105 on the wafer 100 affects the deposition of following low-k dielectric layers. Due to the residue 105, the physical and electrical characteristics of the following low-k dielectric layers are changed. Accordingly, incorrect parameters of the recipe would be set up to run production wafers and undesired low-k dielectric layers would be formed on production wafers.

U.S. Pat. No. 5,092,937 discloses a method of treating semiconductors with surface-treating solutions such as ultra-pure water, dilute hydrofluoric acid and an organic solvent. The semiconductors are then subjected to removal of the surface-treating solutions remaining on the surface of the semiconductor in an inert gas atmosphere of high purity while contacting the surface of the surface-treated semiconductor only with the inert gas of high purity, whereby contamination with impurities on the atomic level from the atmosphere can be prevented.

U.S. Pat. No. 6,068,000 discloses a substrate treatment method to be performed after the steps of forming a desired resist pattern on a substrate and etching thereof. The method comprises steps of: (I) removing the resist pattern on the substrate using a remover solution principally containing a salt derived from hydrofluoric acid and a metal-free base; (II) rinsing said substrate with a lithographic rinsing solution containing a water-soluble organic solvent and water; and (III) washing said substrate with water.

U.S. Pat. No. 6,905,613 discloses a method for using an organic dielectric as a sacrificial layer for forming suspended or otherwise spaced structures. Then, organic solvents only remove organic materials, and thus do not affect or otherwise damage non-organic layers such as metal layers.

U.S. Patent Application No. 2005/0003977 discloses a cleaning composition. The cleaning composition comprises (1) at least one fluoride and/or hydrogendifluoride salt formed from at least one member selected from the group consisting of hydroxylamines, aliphatic amines, aromatic amines, aliphatic quaternary ammonium salts and aromatic quaternary ammonium salts with hydrofluoric acid; (2) at least one organic solvent that includes one or more heteroatoms; and (3) water.

According to the descriptions above, improved methods and apparatus thereof are desired.

### SUMMARY OF THE INVENTION

In some embodiments, a method of semiconductor processing comprises the following steps. An organic solvent is applied over a surface of a material layer on a substrate in which the material layer includes a short-chain structure. A fluorine-containing solution is applied over the surface of the material layer to substantially remove the material layer from the substrate.

In some embodiments, a method comprises the following steps. Acetone is applied over a surface of a trimethylsilane (TMS)-based dielectric layer on a substrate to remove a methyl-group of the TMS-based dielectric layer. The acetone has a temperature from about 18 ° C. to about 40° C., a concentration from about 90 w. % to about 100 w. % and is applied over the surface of the TMS-based dielectric layer for a time of about 100 seconds or more. A deionized (DI) water process is performed over the surface of the TMS-based dielectric layer. A hydrofluoric acid (HF) is applied over the surface of the TMS-based dielectric layer to remove SiOₓ-like material in the TMS-based dielectric layer. The HF has a temperature from about 18° C. to about 70° C. and a concentration from about 1 w. % to about 49 w. %.

In some embodiments, an apparatus for removing a dielectric layer comprises a wafer holder, an organic solvent source and a fluorine solution source. The wafer holder is coupled to the organic solvent source and the fluorine solution source. The wafer holder is adapted to accommodate at least one wafer. The organic solvent source supplies an organic solvent over a surface of an organosilicate material layer on a substrate. The organic solvent has a temperature from about 18° C. to about 40° C., a concentration from about 90 w. % to about 100 w. % and is applied over the substrate for a time of about 100 seconds or more. The fluorine solution source supplies a fluorine-containing solution over the surface of the organosilicate material layer. The fluorine-containing solution has a temperature from about 18° C. to about 70° C. and a concentration from about 1 w. % to about 49 w. %.

The above and other features of the present invention will be better understood from the following detailed description of the preferred embodiments of the invention that is provided in connection with the accompanying drawings.

### BRIEF DESCRIPTION OF THE DRAWINGS

FIG. 1 shows a cross-sectional view of a control wafer according to a prior art procedure of control wafer reclaim.

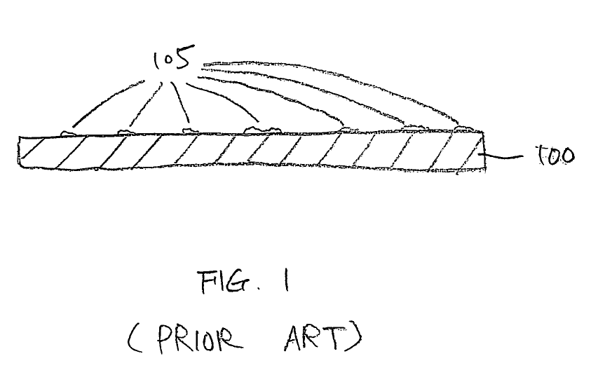

FIG. 2A is a cross-sectional view of an exemplary substrate with a material layer thereon.

FIG. 2B is a flow chart showing an exemplary method of removing a dielectric layer on a substrate.

FIG. 3 is a schematic drawing showing an apparatus for removing a dielectric layer on a substrate according to an embodiment.

### DESCRIPTION OF THE PREFERRED EMBODIMENT

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation.

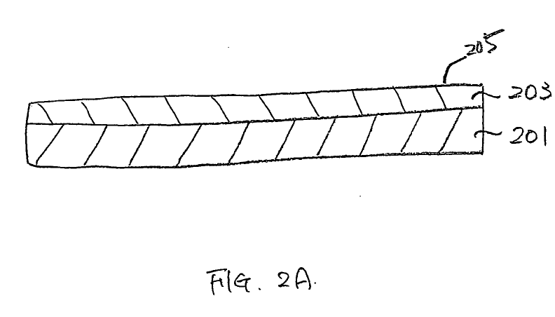

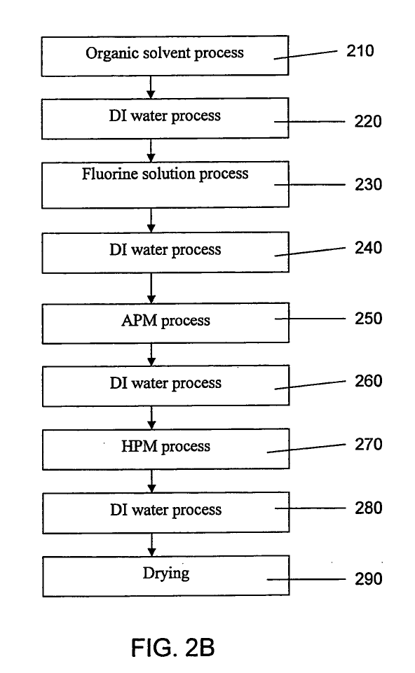

FIG. 2A is a cross-sectional view of an exemplary substrate with a material layer thereon.

Beginning with FIG. 2A, the substrate 201 can be, for example, a silicon substrate, a III-V compound substrate, a glass substrate, a printed circuit board (PCB) or any other substrate similar thereto. In addition, the substrate 201 may comprise various devices thereon to provide desired electrical operations. In this embodiment, the substrate 201 is a blank substrate without any devices thereon.

The material layer 203 is a dielectric layer, and more specifically, is a low-k dielectric layer. The material layer 203 includes a short-chain structure. The short-chain structure includes short-chain polymers that are adapted to be dissolved in organic solvents. The material layer 203 can be an organosilicate material. In some embodiments, the organosilicate material comprises a methyl-based dielectric material, a trimethylsilane-based dielectric material, a tetramethylsilane-based dielectric material, tetramethylcyclotetrasiloxane (ZTOMCATS™²), dimethyldimethoxysilane (Z2DM™²) by Dow Corning of Midland, Mich., or tetrarnethylcyclotetrasiloxane, diethylmethoxysilane (DEMS™) or (porous silica) MesoELK™ provided by AIR PRODUCTS & CHEMICAL CO. of Allentown, Pa. In this embodiment, the material layer 203 comprises a trimethylsilane-based dielectric material.

FIG. 2B is a flow chart showing an exemplary method of removing a dielectric layer on a substrate.

Referring to FIG. 2B, the step 210 applies an organic solvent over the surface 205 of the material layer 203 on the substrate 201 (shown in FIG. 2A). The substrate 201 with the material layer 203 is immersed in a chemical tank with the organic solvent, or the organic solvent is spread on the surface 205 of the material layer 203.

In some embodiments, the organic solvent comprises a polar organic solvent. With polarization, the organic solvent removes a methyl-group from the material layer 203. The polar organic solvent of some embodiments comprises aromatic compounds, alcohols, esters, ethers, ketones, amines, nitrated hydrocarbons, aldehyde, halo-hydrocarbon, halo-aromatic compounds or hydro-aromatic compounds. In this embodiment, the organic solvent comprises acetone. The acetone has a temperature from about 18° C. to about 40° C. The concentration of the acetone is from about 90 w. % to about 100 w. %. The time of the application of the acetone over the surface 205 of the material layer 203 is about 100 seconds or more. Organic solvents have different chemical properties. After reading the descriptions of these embodiment, one skilled in the art can readily adjust conditions of various organic solvents to remove the methyl-group from the organosilicate material set forth above.

The step 210 of some embodiments may also include an ultrasonic process after the organic solvent has been applied to the surface 205 of the material layer 203. For example, the ultrasonic process is performed while the substrate 201 is immersed in a wet bench. The application of the ultrasonic process will enhance the removal rate of methyl-group from the organosilicate material. However, the step 210 can still be executed without the ultrasonic process. One of ordinary skilled in the art, after reading the descriptions of these embodiments, can readily determine whether the ultrasonic process should be added according to the desired process time and clearness level on the substrate 201.

Referring to FIG. 2B, the deionized (DI) water process step 220 is performed. The DI water process step 220 removes the residue of the organic solvent to prevent contamination to subsequent processes. For example, after being removed from the tank with the organic solvent, the substrate 201 is moved into the tank containing DI water. The conditions of the DI water process step 220 are general process parameters of wet bench processes and common knowledge to artisans in this industry. In some embodiments, the DI water process step 220 comprises a high-pressure water process to efficiently remove residue on the surface of the substrate 201. In other embodiments, the DI water process step 220 may be omitted to reduce costs or due to other process concerns. According to the descriptions of these embodiments, one skilled in the art can determine whether the DI water process step 220 should be performed.

The DI water process step 220 of some embodiments also includes an ultrasonic process after DI water has been applied to the surface 205 of the material layer 203. For example, the ultrasonic process is performed while the substrate 201 is immersed in a wet bench. The application of the ultrasonic process will enhance the removal rate of organic solvent residue on the substrate 201. However, the DI water process step 220 can still be executed without the ultrasonic process. One of ordinary skill in the art, after reading the descriptions of these embodiments, can determine whether the ultrasonic process should be added according to the desired process time and clearness level on the substrate 201.

The fluorine-containing solution step 230 is then performed. The fluorine-containing solution is applied over the surface 205 of the material layer 203 (shown in FIG. 2A). The fluorine-containing solution step 230 is adapted to remove SiOₓ-like material from the material layer 203. The SiOₓ-like material, such as silicon oxide and SiCO:H, has Si—O bonds. Fluorine ions react with Si ions of the material to form SiF₄ which desorbs from the exposed surface of the material. In some embodiments, the fluorine-containing solution comprises hydrofluoric acid (HF). The hydrofluoric acid includes a temperature from about 18° C. to about 70° C. The concentration of the hydrofluoric acid is from about 1 w. % to about 49 w. %.

In some embodiments, the step 230 also includes an ultrasonic process after the fluorine-containing solution has been applied to the surface 205 of the material layer 203. For example, the ultrasonic process is performed while the substrate 201 is immersed in a wet bench. The application of the ultrasonic process will enhance the removal rate of SiOₓ-like material from the material layer 203. However, the step 230 can still be executed without the ultrasonic process. One of ordinary skill in the art, after reading the descriptions of these embodiments, can determine whether the ultrasonic process should be added according to the desired process time and clearness level on the substrate 201. After the step 230, the material layer 203 on the substrate 201 is substantially removed. In this embodiment, the substrate 201 is a blank wafer, e.g., a control wafer. The substrate 201 is then transferred to a chemical vapor deposition (CVD) stop for recycling.

Referring to FIG. 2B, another deionized (DI) water process step 240 is performed. The purpose and condition of the DI water process step 240 is similar to those of the DI water process step 220. Detailed descriptions are not repeated.

In some embodiments, the DI water process step 240 also includes an ultrasonic process after DI water has been applied to the surface 205 of the material layer 203. The descriptions of the ultrasonic process are similar to those set forth above in connection with the DI water process step 220. Detailed descriptions are not repeated.

Referring to FIG. 2B, the ammonium hydroxide-hydrogen peroxide mixture (APM) process step 250 is performed. The APM process is a standard cleaning process with a mixed solution of NH₄OH, H₂O₂ and DI water with a ratio about 1:1:5 in volume. The APM process removes particles on the substrate 201. The typical temperature of the APM solution is about 70 ° C. Because the APM process is a standard cleaning procedure within semiconductor technology, detailed descriptions are not provided herein.

In some embodiments, the step 250 also includes an ultrasonic process after the APM process is performed. For example, the ultrasonic process is performed while the substrate 201 is immersed in a wet bench. The application of the ultrasonic process efficiently removes particles on the substrate 201. However, the step 250 can be executed without the ultrasonic process. One of ordinary skilled in the art, after reading the descriptions of these embodiments, can readily determine whether the ultrasonic process should be added according to the desired process time and clearness level on the substrate 201.

Referring to FIG. 2B, the deionized (DI) water process step 260 is performed. The purpose and condition of the DI water process step 260 is similar to those of the DI water process step 220. Detailed descriptions are not repeated.

In some embodiments, the DI water process step 260 also includes an ultrasonic process while the DI water process 260 is performed. The descriptions of the ultrasonic process are similar to those set forth above in connection with the DI water process step 220. Detailed descriptions are not repeated.

Referring to FIG. 2B, the hydrochloric acid—hydrogen peroxide mixture (HPM) process step 270 is performed. The HPM process is a standard cleaning process with a mixed solution of HCl, H₂O₂ and DI water with a ratio of about 1:1:6 by volume. The HPM process removes metallic particles on the substrate 201. The typical temperature of the HPM solution is about 70° C. The time for the HPM process is from about 5 minutes to about 10 minutes. Because the HPM process is a standard cleaning procedure within semiconductor technology, detailed descriptions are not provided herein.

In some embodiments, the step 270 also includes an ultrasonic process after the HPM process is performed. For example, the ultrasonic process may be performed while the substrate 201 is immersed in a wet bench. The application of the ultrasonic process efficiently removes metallic particles on the substrate 201. However, the step 270 can be executed without the ultrasonic process. One of ordinary skilled in the art, after reading the descriptions of these embodiments, can readily determine whether the ultrasonic process should be added according to the desired process time and clearness level on the substrate 201.

Referring to FIG. 2B, the deionized (DI) water process step 280 is performed. The purpose and condition of the DI water process step 280 is similar to those of the DI water process step 220. Detailed descriptions are not repeated.

In some embodiments, the DI water process step 280 also includes an ultrasonic process while the DI water process 280 is performed. The descriptions of the ultrasonic process are similar to those set forth above in connection with the DI water process step 280. Detailed descriptions are not repeated.

Referring to FIG. 2B, the step 290 dries the substrate 205. In one embodiment of the step 290, the substrate 205 is transferred to a stage or a chamber comprising a heater or fan to remove residual water thereon.

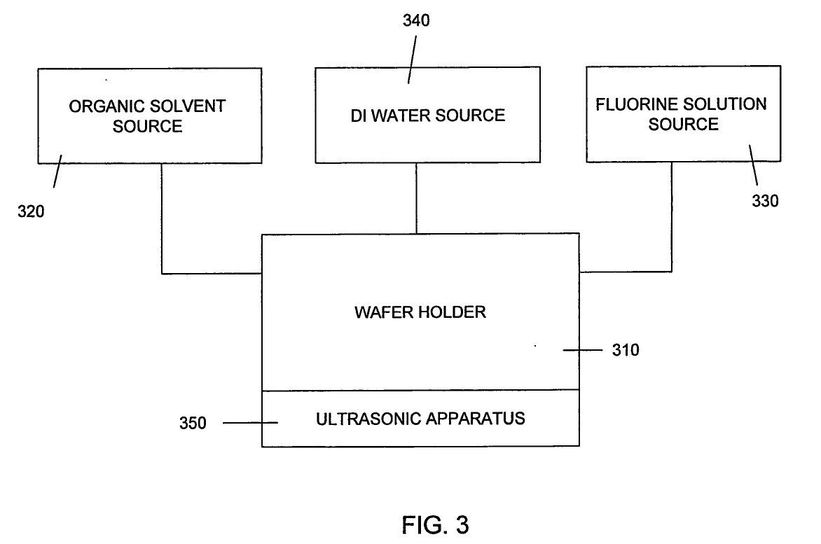

FIG. 3 is a schematic drawing showing an apparatus for removing a dielectric layer on a substrate according to an embodiment.

Referring to FIG. 3, the apparatus comprises a wafer holder 310, an organic solvent source 320, a fluorine solution source 330, a DI water source 340 and a ultrasonic apparatus 350. The wafer holder 310 is coupled to the organic solvent source 320, the fluorine solution source 330, the DI water source 340 and the ultrasonic apparatus 350.

The wafer holder 310 is adapted to accommodate at least one wafer. In the wet-bench embodiments, for example, the wafer holder 310 comprises a chemical bench in which various solutions are supplied by the organic solvent source 320, the fluorine-containing source 330 and the DI water source 340 according to the process flow shown in FIG. 2B. There is a wafer boat in the chemical bench to accommodate wafers. In some embodiments, the wafer holder 310 comprises a robot to transfer the substrate 205 (shown in FIG. 2A) among the organic solvent source 320, the fluorine-containing source 330 and the DI water source 340 according to the process flow shown in FIG. 2B. In some embodiments, the wafer holder 310 comprises a wafer stage to clamp the substrate 205 (shown in FIG. 2A). Various solutions provided from the organic solvent source 320, the fluorine-containing source 330 and the DI water source 340 are spread over the substrate 205 according to the process flow shown in FIG. 2B.

Referring to FIG. 3, the organic solvent source 320 supplies an organic solvent over the surface 205 of the material layer 203 on the substrate 201 (shown in FIG. 2A). The organic solvent source 320 can be, for example, an inlet valve, a tank, a container, a liquid spreader or other apparatus which are adapted to provide the corresponding solvent. In this embodiment, the organic solvent comprises acetone. The acetone has a temperature from about 18° C. to about 40 ° C. The concentration of the acetone is from about 90 w. % to about 100 w. %. The time of application of the acetone over the surface 205 of the material layer 203 is about 100 seconds or more.

Referring to FIG. 3, the fluorine solution source 330 supplies a fluorine-containing solution over the surface 205 of the material layer 203. The fluorine solution source 330 can be, for example, can be, for example, an inlet valve, a tank, a container, a liquid spreader or other apparatus which are adapted to provide the corresponding solution. In this embodiment, the fluorine solution comprises HF. The HF has a temperature from about 18° C. to about 70° C. The concentration of HF is from about 1 w. % to about 49 w. %.

Referring to FIG. 3, the DI water source 340 supplies DI water over the surface 205 of the material layer 203. The DI water source 340 can be an inlet valve, a tank, a container, a liquid spreader or other apparatus which are adapted to provide the corresponding solution, for example. The DI water source 340 performs the function described in process steps 220, 240, 260 and 280 set forth above in connection with FIG. 2B. Detailed descriptions are not repeated. In some embodiments, the apparatus comprises more than one DI water source due to equipment design or process concerns. In other embodiments, the DI water source 340 is not required. Wafers after the process steps, such as organic solvent process 210, fluorine solution process 230, the APM process 250 and HPM process 270 set forth in FIG. 2B, are transferred to an oven or a chamber with a fan for drying. The elimination of the DI water source 340 reduces the size of the apparatus and also cuts down process time.

Referring to FIG. 3, the ultrasonic apparatus 350 provides ultrasonic process while the process steps 210-280 of FIG. 2B are performed. As set forth above, the ultrasonic process efficiently remove solvent residue or particles on the substrate 203. Detailed descriptions are not repeated. In some embodiments, the ultrasonic apparatus 350 is not required. The elimination of the ultrasonic apparatus 350 reduces the size of the apparatus and also reduces process time.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

1. A method of semiconductor processing, comprising the steps of:
applying an organic solvent over a surface of an organosilicate material layer on a substrate, the organosilicate material layer including a short-chain structure, wherein the organic solvent is at least one of the group consisting of acetone, aromatic compounds, alcohols, esters, ethers, ketones, amines, nitrated hydrocarbons, aldehyde, halo-hydrgcoxbon, halo-aromatic compounds and hydro-aromatic compounds; and
applying a fluorine-containing solution over the surface of the organosilicate material layer to substantially remove the organosilicate material layer from the substrate.

2. (canceled)

3. (canceled)

4. (canceled)

5. The method of claim 1, wherein the acetone has a temperature from about 18° C. to about 40° C. and a concentration from about 90 w. % to about 100 w. % and is applied over the surface of the material layer for about 100 seconds or more.

6. (canceled)

7. The method of claim 1, wherein the organosilicate material is at least one selected from a group consisting of a methyl-based dielectric material, trimethylsilane-based dielectric material, a tetramethylsilane-based dielectric material, tetramethylcyclotetrasiloxane, dimethyldimethoxysilane, diethylmethoxysilane and porous silica.

8. The method of claim 1, wherein the step of applying the organic solvent comprises removing a methyl-group from the organosilicate material.

9. The method of claim 1, wherein the fluorine-containing solution comprises hydrofluoric acid (HF).

10. The method of claim 9, wherein the hydrofluoric acid comprises a temperature from about 18° C. to about 70° C. and a concentration from about 1 w. % to about 49 w. %.

11. The method of claim 1, wherein the step of applying the fluorine-containing solution over the surface of the material layer comprises removing an SiOₓ-like material.

12. The method of claim 1 further comprising perforning a deionized water process between the step of applying the organic solvent and the step of applying the fluorine-containing solution.

13. The method of claim 1 further comprising performing at least one of an APM process and an HPM process.

14. The method of claim 1, wherein at least one of the step of applying the organic solvent and the step of applying the fluorine-containing solution comprises an ultrasonic process.

15. A method of semiconductor processing, comprising the steps of:
applying acetone over a surface of a trimethylsilane (TMS)-based dielectric layer on a substrate to remove a methyl-group of the TMS-based dielectric layer, wherein the acetone has a temperature from about 18° C. to about 40° C., a concentration from about 90 w. % to about 100 w. % and is applied over the surface of the TMS-based dielectric layer about 100 seconds or more;
performing a deionized (DI) water process over the surface of the TMS-based dielectric layer; and
applying a hydrofluoric acid (HF) over the surface of the TMS-based dielectric layer to remove SiOₓ-like material in the TMS-based dielectric layer, wherein the HF has a temperature from about 18° C. to about 70° C. and a concentration from about 1 w. % to about 49 w. %.

16. The method of claim 15, wherein at least one of the step of applying the acetone, the step of DI water process and the step of applying the HP comprises an ultrasonic process.

17. The method of claim 15 further comprising performing at least one of an APM process and an HPM process.

18. An apparatus for removing a dielectric layer, comprising:
a wafer holder adapted to accommodate at least one wafer;
an organic solvent source coupled to the wafer holder, supplying an organic solvent over a surface of an organosilicate material layer on a substrate, wherein the organic solvent has a temperature from about 18° C. to about 40° C., a concentration from about 90 w. % to about 100 w. % and is applied over the surface of the organosilicate material layer about 100 seconds or more; and
a fluorine solution source coupled to the wafer holder, supplying, a fluorine solution over the surface of the organosilicate material layer, wherein the fluorine solution has a temperature from about 18° C. to about 70° C. and a concentration from about 1 w. % to about 49 w. %.

19. The apparatus of claim 18, further comprising a deionized (DI) water source coupled to the wafer holder to provide DI water over the surface of the organosilicate material layer.

20. The apparatus of claim 18, further comprising an ultrasonic apparatus coupled to the wafer holder to perform an ultrasonic process while at least one of the organic solvent source and the fluorine solution source provides the corresponding solution.
